(19) United States
(12) Patent Application Publication
(10) Pub. No.: US 2019/0072798 A1
(43) Pub. Date: Mar. 7, 2019

(54) TOUCH-PANEL-EQUIPPED DISPLAY DEVICE

(71) Applicant: SHARP KABUSHIKI KAISHA, Sakai City, Osaka (JP)

(72) Inventor: HIROSHI AICHI, Sakai City (JP)

(21) Appl. No.: 16/093,622

(22) PCT Filed: Apr. 12, 2017
(86) PCT No.: PCT/JP2017/014988

§ 371 Date: Oct. 13, 2018

(30) Foreign Application Priority Data
Apr. 13, 2016 (JP) 2016-080190

(51) Int. Cl. G02F 1/1333; G06F 3/041; G06F 3/044; G02F 1/1343; H01L 27/12

(52) U.S. Cl. CPC G02F 1/13338; G06F 3/0412; G06F 3/044; G02F 1/133514; H01L 27/124; G02F 2201/123; G02F 1/134309

(57) ABSTRACT

A touch-panel-equipped display device includes display control elements formed on an active matrix substrate; a plurality of pixel electrodes formed on the active matrix substrate; a plurality of counter electrodes that are formed on the active matrix substrate, electrostatic capacitors being formed between the counter electrodes and the pixel electrodes; a control unit that supplies a touch driving signal to the counter electrodes so as to detect a touch position; and touch sensor lines for supplying the touch driving signal from the control unit to the counter electrodes. On a counter substrate, a color filter that includes at least blue color areas 51b, green color areas 51g, and red color areas 51r is provided, and at a boundary between the blue color area 51b and another color area of the color filter, the touch sensor line 22 is arranged so as to be offset toward the blue color area 51b side.

### TECHNICAL FIELD

The present invention relates to a touch-panel-equipped display device.

### BACKGROUND ART

In recent years, a touch-panel-equipped display device incorporating a touch panel has been widely used. Recently, further, a so-called in-cell type touch-panel-equipped display device in which lines and the like necessary for detecting a touch position are formed within a display panel has been known.

As one example of such known touch-panel-equipped display devices, a touch-sensor-integrated type display device is disclosed in Patent Document 1. In this touch-sensor-integrated type display device, a plurality of common electrodes opposed to pixel electrodes double as touch driving electrodes and touch sensing electrodes that compose a touch sensor. To each of the touch sensing electrode, a touch driving electrode connection line is connected.

### PRIOR ART DOCUMENT

### Patent Document

Patent Document 1: JP-A-2015-106411

### SUMMARY OF THE INVENTION

### Problem to be Solved by the Invention

Lines such as a touch driving electrode connection line mentioned above is formed generally by etching a metal film. It is therefore difficult to control the line width or the tapering angle of the end faces, etc., so that they are strictly uniform.

As illustrated in FIGS. 10 and 11, the angle at which light incident in an oblique direction is reflected varies, for example, due to differences in the tapering angles of line end faces. In FIGS. 10 and 11, “91” denotes an active matrix substrate, “94” denotes a touch driving electrode connection line, “93” denotes a liquid crystal layer, “91r” denotes a color filter of red color, “91b” denotes a color filter of blue color, “91BM” denotes a black matrix, and “92” denotes a filter substrate. In the configuration illustrated in FIG. 10, the tapering angle of the end face of the touch driving electrode connection line 94 is greater as compared with the configuration illustrated in FIG. 11, and light incident on the end face of the line 94 is reflected and returned toward the viewer side. On the other hand, in the configuration illustrated in FIG. 11, the tapering angle of the end face of the line 94 is smaller as compared with the configuration illustrated in FIG. 10, and light reflected at the end face is not returned to the viewer side.

In a case where the angle at which the incoming beam is reflected on the touch driving electrode connection line varies in this way, the intensity distribution of the reflection light becomes non-uniform in the panel surface, which results in that display irregularities are visible to a viewer.

In light of the above-described problem, it is an object of the present invention to provide a touch-sensor-integrated type display device in which display irregularities caused by lines for diving touch sensors are reduced.

### Means to Solve the Problem

To achieve the above-described object, the touch-panel-equipped display device disclosed herein includes:

an active matrix substrate;

a counter substrate opposed to the active matrix substrate;

a liquid crystal layer interposed between the active matrix substrate and the counter substrate;

a display control element formed on the active matrix substrate;

a plurality of pixel electrodes formed on the active matrix substrate;

a plurality of counter electrodes that are formed on the active matrix substrate, electrostatic capacitors being formed between the counter electrodes and the pixel electrodes;

a control unit that supplies a touch driving signal to the counter electrodes so as to detect a touch position; and

a touch sensor line for connecting the control unit and the counter electrodes, and supplying the touch driving signal from the control unit to the counter electrodes,

wherein a color filter that includes at least a blue color area, a green color area, and a red color area is provided on the counter substrate, and

the touch sensor line is arranged so as to be offset toward a blue color area side at a boundary between the blue color area and another color area of the color filter.

### Effect of the Invention

With a touch-sensor-integrated type display device disclosed below, display irregularities caused by lines for diving touch sensors can be reduced.

### BRIEF DESCRIPTION OF DRAWINGS

FIG. 1 is a cross-sectional view illustrating a touch-panel-equipped display device in Embodiment 1.

FIG. 2 illustrates an exemplary arrangement of counter electrodes formed on an active matrix substrate.

FIG. 3 is an enlarged view of a part of an area of the active matrix substrate.

FIG. 4 is a cross-sectional view of the active matrix substrate.

FIG. 5 is a schematic cross-sectional view illustrating a position of a touch sensor line arranged along a boundary between a blue color area and a red color area.

FIG. 6 is a schematic cross-sectional view illustrating a position of a touch sensor line arranged along a boundary between a red color area and a green color area.

FIG. 7 is a plan view illustrating an exemplary arrangement of touch sensor lines.

FIG. 8 is a plan view illustrating another exemplary arrangement of touch sensor lines.

FIG. 9 is a schematic plan view illustrating a configuration of a touch sensor line in a touch-panel-equipped display device according to Embodiment 2.

FIG. 10 is a schematic cross-sectional view for explaining a cause of display irregularities in a conventional touch-panel-equipped display device.

FIG. 11 is a schematic cross-sectional view for explaining a cause of display irregularities in a conventional touch-panel-equipped display device.

### MODE FOR CARRYING OUT THE INVENTION

A touch-panel-equipped display device according to a first configuration of the present invention includes:

an active matrix substrate;

a counter substrate opposed to the active matrix substrate;

a liquid crystal layer interposed between the active matrix substrate and the counter substrate;

a display control element formed on the active matrix substrate;

a plurality of pixel electrodes formed on the active matrix substrate;

a plurality of counter electrodes that are formed on the active matrix substrate, electrostatic capacitors being formed between the counter electrodes and the pixel electrodes;

a control unit that supplies a touch driving signal to the counter electrodes so as to detect a touch position; and

a touch sensor line for connecting the control unit and the counter electrodes, and supplying the touch driving signal from the control unit to the counter electrodes,

wherein a color filter that includes at least a blue color area, a green color area, and a red color area is provided on the counter substrate, and

the touch sensor line is arranged so as to be offset toward a blue color area side at a boundary between the blue color area and another color area of the color filter.

In this first configuration, a touch sensor line for supplying a touch driving signal from a control unit to counter electrodes is arranged so as to be offset toward a blue color area side at a boundary between the blue color area and another color area of the color filter.

With this configuration, as compared with the amount of reflection light that is reflected by the touch sensor line, passes through the blue color area, and is returned to the viewer side, the amount of reflection light that is returned passing through the other color areas is smaller. Since the human eye has weaker sensitivity with respect to light of blue color, the configuration described above makes it possible to suppress display irregularities due to reflection light from the touch sensor line.

A second configuration of the present invention is the first configuration further characterized in that the touch sensor lines are arranged on both opposite sides of the blue color area of the color filter.

With this configuration, the amount of reflection light returned from the areas of the colors other than the blue color in the color filter to the viewer side can be made smaller, as compared with the amount of reflection light returned from the blue color area, whereby display irregularities due to reflection light from the touch sensor lines can be more effectively suppressed.

A third configuration of the present invention is the first configuration further characterized in that the touch sensor line includes a first portion arranged on one of opposite sides of the blue color area of the color filter, a second portion arranged on the other one of the opposite sides of the blue color area of the color filter, and a third portion that connects the first portion and the second portion.

According to this configuration, one touch sensor line includes a first portion arranged on one of the sides of the blue color area of the color filter, a second portion arranged on the other side of the blue color area of the color filter, and a third portion that connects the first portion and the second portion, thereby being provided in a zig-zag shape. With this configuration, differences in the amount of reflected light from the touch sensor line can be reduced on both of the sides of the blue color area. As a result, display irregularities due to reflection light from the touch sensor line can be more effectively suppressed.

In the third configuration, the first portions and the second portions may be arranged alternately every other pixel region.

### Embodiment

The following description describes embodiments of the present invention in detail, while referring to the drawings. Identical or equivalent parts in the drawings are denoted by the same reference numerals, and the descriptions of the same are not repeated. To make the description easy to understand, in the drawings referred to hereinafter, the configurations are simply illustrated or schematically illustrated, or the illustration of a part of constituent members is omitted. Further, the dimension ratios of the constituent members illustrated in the drawings do not necessarily indicate the real dimension ratios.

### Embodiment 1

### [1. Overall Configuration]

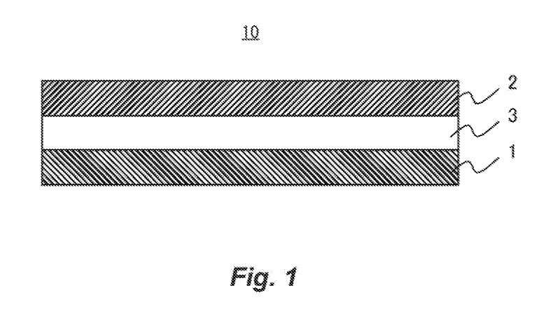

First of all, the following description describes an overall configuration of a touch-panel-equipped display device 10 according to one embodiment of the present invention while referring to FIGS. 1 to 4.

FIG. 1 is a cross-sectional view of a touch-panel-equipped display device 10. The touch-panel-equipped display device 10 in one embodiment includes an active matrix substrate 1, a counter substrate 2, and a liquid crystal layer 3 interposed between the active matrix substrate 1 and the counter substrate 2. Each of the active matrix substrate 1 and the counter substrate 2 includes a glass substrate that is substantially transparent (has high translucency). The counter substrate 2 includes color filters that are not illustrated. Further, though the illustration is omitted, this touch-panel-equipped display device 10 includes a backlight.

The touch-panel-equipped display device 10 in the present embodiment has a function of displaying an image, and at the same time, has a function of detecting position information that a user inputs (touch position), based on the displayed image. This touch-panel-equipped display device 10 includes a so-called in-cell type touch panel in which lines and the like necessary for detecting a touch position are formed in a display panel.

In the case of the touch-panel-equipped display device 10 in the present embodiment, the method for driving liquid crystal molecules contained in the liquid crystal layer 3 is the horizontal electric field driving method. To realize the horizontal electric field driving method, pixel electrodes and counter electrodes (referred to as “common electrodes” in some cases) for forming electric fields are formed on the active matrix substrate 1.

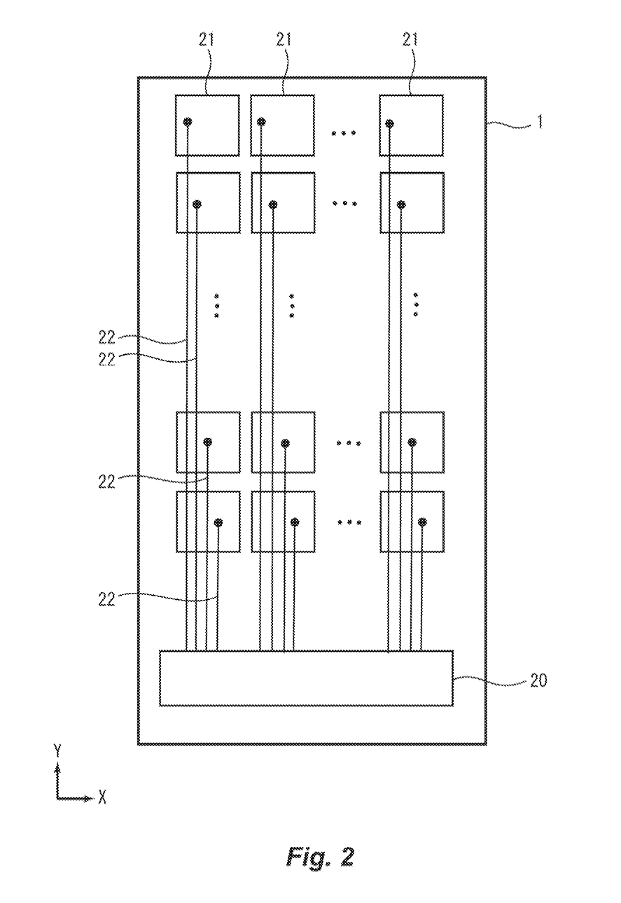

FIG. 2 illustrates an exemplary arrangement of the counter electrodes 21 formed on the active matrix substrate 1. The counter electrodes 21 are formed on a surface of the liquid crystal layer 3 side of the active matrix substrate 1. As illustrated in FIG. 2, each counter electrode 21 is in a rectangular shape, and a plurality of the same are arranged in matrix on the active matrix substrate 1.

On the active matrix substrate 1, a controller (control unit) 20 is provided. The controller 20 performs a controlling operation for displaying an image, and at the same time, performs a controlling operation for detecting a touch position.

The controller 20 and the counter electrodes 21 are connected by touch sensor lines 22 extending in the Y axis direction. More specifically, the same number of the touch sensor lines 22 as the number of the counter electrodes 21 are formed on the active matrix substrate 1.

In the touch-panel-equipped display device 10 in the present embodiment, the counter electrodes 21 in pairs with the pixel electrodes form electrostatic capacitors and are used during the controlling operation for image display, and are also used during the controlling operation for touch position detection.

Regarding the counter electrodes 21, parasitic capacitors are formed between the same and adjacent ones of the counter electrodes 21 or the like. When a human finger or the like touches the display screen of the display device 10, capacitors are formed between the counter electrodes 21 and the human finger or the like, and electrostatic capacitances increase. During the control operation for touch position detection, the controller 20 supplies a touch driving signal to the counter electrodes 21 through the touch sensor lines 22, and receives a touch detection signal through the touch sensor lines 22. By doing so, the controller 20 detects a change in the electrostatic capacitances, and detects a touch position. In other words, the touch sensor lines 22 function as lines for the transmission/reception of the touch driving signal and the touch detection signal.

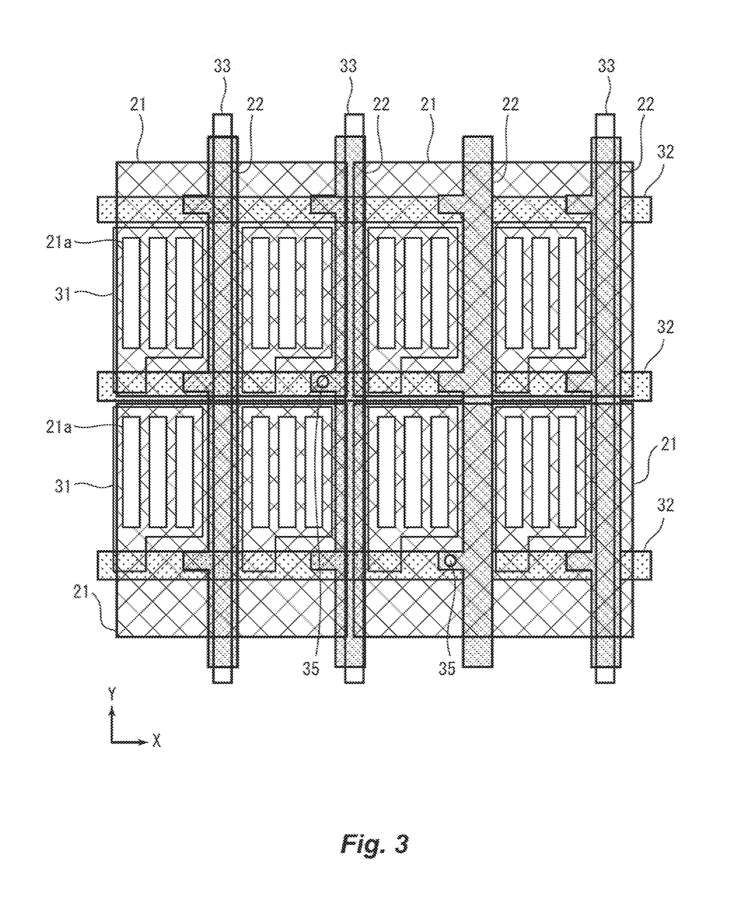

FIG. 3 is an enlarged view of a part of the area of the active matrix substrate 1. As illustrated in FIG. 3, a plurality of pixel electrodes 31 are arranged in matrix. Further, though the illustration is omitted in FIG. 3, thin film transistors (TFTs) as display control elements are also arranged in matrix in correspondence to the pixel electrodes 31, respectively. The counter electrodes 21 are provided with a plurality of slits 21a.

Around the pixel electrodes 31, the gate lines 32 and the source lines 33 are provided. The gate line 32 extends in the X axis direction, and a plurality of the same are arrayed at predetermined intervals in the Y axis direction. The source line 33 extends in the Y axis direction, and a plurality of the same are arrayed at predetermined intervals in the X axis direction. In other words, the gate lines 32 and the source lines 33 are formed in a lattice form, and the pixel electrodes 31 are provided in the areas defined by the gate lines 32 and the source lines 33, respectively.

On the counter substrate 2, color filter of three colors of R, G, and B are provided so as to correspond to the pixel electrodes 31, respectively. With this configuration, each of the pixel electrodes 31 functions as a subpixel of any one of the colors of R, G, and B.

As illustrated in FIG. 3, the touch sensor line 22 extending in the Y axis direction are arranged so as to partially overlap, in the normal line direction of the active matrix substrate 1, with the source lines 33 extending in the Y axis direction. More specifically, the touch sensor lines 22 are provided in a layer upper (on the liquid crystal layer side) with respect to the source lines 33, and the touch sensor lines 22 and the source line 33 partially overlap with each other in plan view.

In FIG. 3, white circles 35 indicate portions at which the counter electrodes 21 and the touch sensor line 22 are connected with each other.

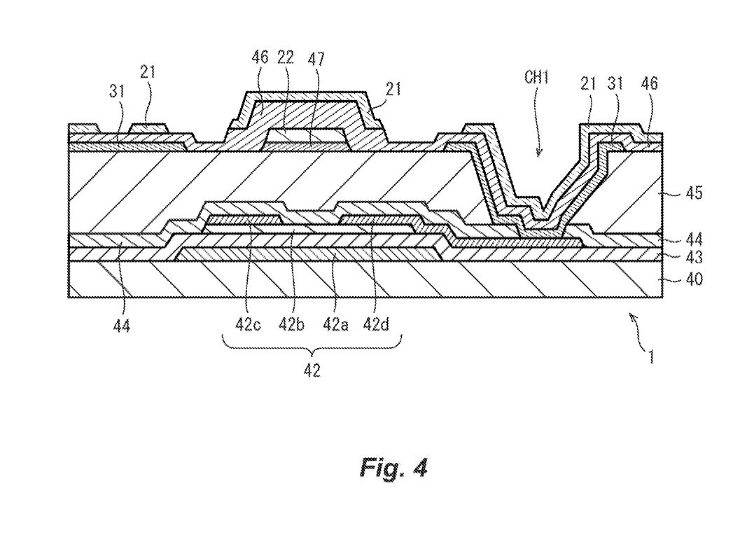

FIG. 4 is a cross-sectional view of the active matrix substrate 1 at a position where a TFT 42 is included. On the glass substrate 40, the TFT 42, which is a display control element, is provided. The TFT 42 includes a gate electrode 42a, a semiconductor film 42b, a source electrode 42c, and a drain electrode 42d.

The gate electrode 42a of the TFT 42 is formed on the glass substrate 40. The gate electrode 42a is formed with, for example, a laminate film made of titanium (Ti) and copper (Cu). Though not illustrated in FIG. 4, the gate line 32 is also formed on the glass substrate, in the same layer as the layer where the gate electrode 42a is formed.

A gate insulating film 43 is formed so as to cover the gate electrode 42a. The gate insulating film 43 is made of, for example, silicon nitride (SiNx) or silicon dioxide (SiO₂).

On the gate insulating film 43, the semiconductor film 42b is formed. The semiconductor film 42b is, for example, an oxide semiconductor film, which may contain at least one metal element among In, Ga, and Zn. In the present embodiment, the semiconductor film 42b contains, for example, an In-Ga-Zn-O-based semiconductor. Here, the In-Ga-Zn-O-based semiconductor is a ternary oxide of indium (In), gallium (Ga), and zinc (Zn), in which the ratio (composition ratio) of In, Ga, and Zn is not limited particularly, and examples of the ratio include In:Ga:Zn=2:2:1, In:Ga:Zn=1:1:1, and In:Ga:Zn=1:1:2.

The source electrode 42c and the drain electrode 42d are provided on the semiconductor film 42b so as to be distanced from each other. The source electrode 42c and the drain electrode 42d are formed with, for example, laminate films made of titanium (Ti) and copper (Cu). Though not illustrated in FIG. 4, the source line 33 is formed in the same layer as that where the source electrode 42c is formed.

A first insulating film 44 is formed so as to cover the source electrode 42c and the drain electrode 42d. The first insulating film 44 is made of, for example, silicon nitride (SiNₓ) or silicon dioxide (SiO₂).

On the first insulating film 44, a flattening film 45, which is an insulator, is formed. The flattening film 45 is made of, for example, an acrylic resin material such as polymethyl methacrylate resin (PMMA). The flattening film 45, however, can be omitted.

On the flattening film 45, the pixel electrode 31 is formed. The pixel electrode 31 is a transparent electrode, and is made of a material such as, for example, indium tin oxide (ITO), zinc oxide (ZnO), indium zinc oxide (IZO), indium gallium zinc oxide (IGZO), or indium tin zinc oxide (ITZO).

On the flattening film 45, a conductive film 47 is formed as well. This conductive film 47 is a transparent electrode film made of the same material as that of the pixel electrode 31. The conductive film 47 is provided for a purpose of improving the adhesion between the touch sensor line 22 and the flattening film 45. In a case where high adhesion is achieved between the touch sensor line 22 and the flattening film 45, therefore, the conductive film 47 can be omitted.

On the conductive film 47, the touch sensor line 22 is formed. The touch sensor line 22 is made of, for example, any one of copper (Cu), titanium (Ti), molybdenum (Mo), aluminum (Al), magnesium (Mg), cobalt (Co), chromium (Cr), tungsten (W), and cadmium (Cd), or alternatively, a mixture of any of these. In a case where the conductive film 47 is omitted, the touch sensor line 22 is formed on the flattening film 45.

A second insulating film 46 is formed so as to cover the pixel electrode 31 and the touch sensor line 22. The second insulating film 46 is made of, for example, silicon nitride (SiNₓ) or silicon dioxide (SiO₂).

On the second insulating film 46, the counter electrode 21 is formed. In the second insulating film 46, an opening 46a for allowing the counter electrode 21 and the touch sensor line 22 to be connected with each other is provided. The counter electrode 21 is in contact with the touch sensor line 22 at an opening 46a portion in the second insulating film 46. The counter electrode 21 is a transparent electrode, made of a material such as, for example, ITO, ZnO, IZO, IGZO, or ITZO.

In the first insulating film 44 and the flattening film 45, a contact hole CH1 is formed. The pixel electrode 31 is in contact with the drain electrode 42d of the TFT 42, through the contact hole CH1.

In the present embodiment, as illustrated in FIG. 4, the touch sensor line 22 is formed on the flattening film 45, more specifically, on the conductive film 47. In other words, as compared with a configuration in which a touch sensor line is formed in the layer where the TFT 42 is formed, such as the layer where the gate line 32 is formed or the layer where the source line 33 is formed, the touch sensor line 22 is arranged at a position closer to the panel surface, and accordingly, the touch sensor has a higher sensing sensitivity.

Supposing that the touch sensor line 22 is provided in a layer upper with respect to the counter electrode 21, since the liquid crystal layer 3 is present above the counter electrode 21 in this case, there is possibility that display image is affected (display noises occur) during the controlling operation for touch position detection. In the present embodiment, however, as illustrated in FIG. 4, the touch sensor line 22 is provided in a layer that is upper with respect to the TFT 42 and lower with respect to the counter electrode 21, and this makes it possible to suppress influences to a display image during the controlling operation for touch position detection.

In the present embodiment, the touch sensor line 22 is formed in the same layer as that where the pixel electrode 31 is formed (more precisely, the pixel electrode 31 and the conductive film 47 are provided in the same layer, and the touch sensor line 22 is provided in a layer upper with respect to the conductive film 47). Supposing that the touch sensor line 22 is provided below the pixel electrode 31, it is necessary to laminate the touch sensor line, the insulating film, the pixel electrode, the insulating film, and the counter electrode in the stated order, which means that two insulating films are needed. In the configuration of the present embodiment, however, the touch sensor line 22 is provided in the same layer as that of the pixel electrode 31, and only one insulating film is therefore needed for insulation between the counter electrode 21 and the pixel electrode 31 as well as the touch sensor line 22; that is, only the second insulating film 46 is needed.

Further, in the present embodiment, the touch sensor line 22 is arranged in such a manner that the first insulating film 44 and the flattening film 45 are interposed between the touch sensor line 22 and the gate line 32 as well as the source line 33. Parasitic capacitances between the touch sensor line 22 and the gate line 32 as well as the source line 33 are therefore small, and this makes it possible to suppress reductions in the sensing sensitivity of the touch panel.

Still further, since the touch sensor line 22 is formed so as to partially overlap with the gate electrode 42a as illustrated in FIG. 4, the transmittance does not drastically decrease. For example, if the touch sensor line is formed in the same layer as that where the gate electrode 42a is formed, the transmittance accordingly decreases for the touch sensor line. With the configuration of the present embodiment, however, the transmittance can be improved, as compared with a configuration in which the touch sensor line is formed in the same layer as that where the gate electrode 42a is formed.

### [2. Position Relationship Between Touch Sensor Line 22 and Color Filter 51]

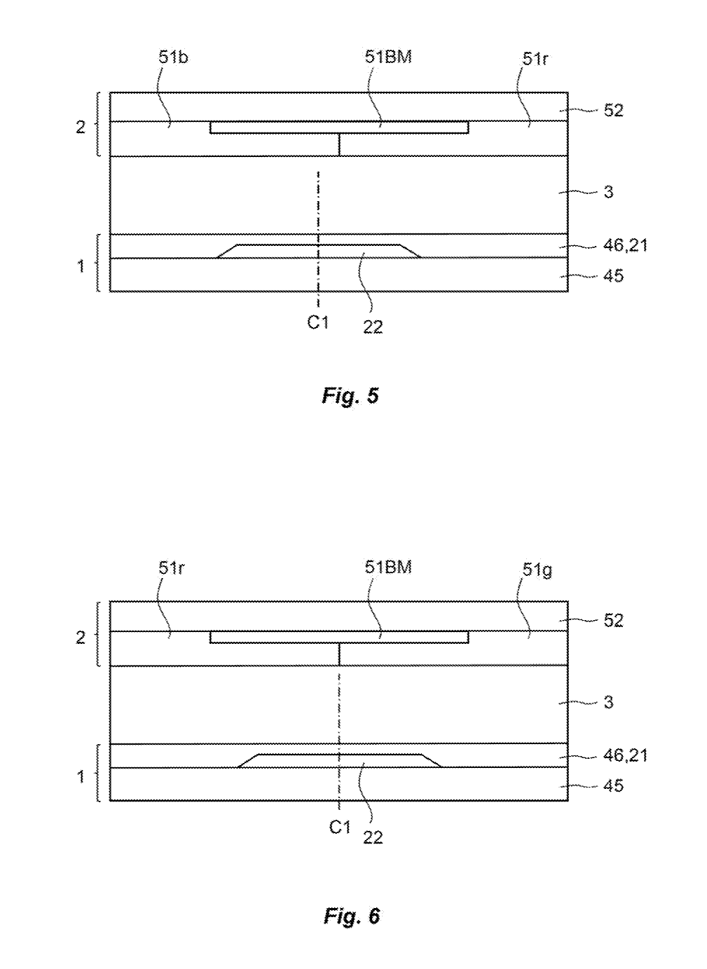

Next, the following description describes the position relationship between the touch sensor line 22 and the color filter 51, while referring principally to FIGS. 5 and 6.

The touch sensor line 22 extends in the Y axis direction in parallel with the source line 33, as illustrated in FIGS. 2 and 3. In the touch-panel-equipped display device 10 in the present embodiment, at the boundary between the blue color (B) area and the areas of the other colors (R or G) of the color filter (pixel), the touch sensor line 22 is offset toward the blue color area when viewed in a plan view.

FIG. 5 is a schematic cross-sectional view illustrating the position of the touch sensor line 22 arranged at the boundary between the blue color area and red color area. FIG. 6 is a schematic cross-sectional view illustrating the position of the touch sensor line 22 arranged at the boundary between the red color area and green color area. FIGS. 5 and 6 schematically illustrate cross sections of the touch-panel-equipped display device 10, taken along the X-Z plane, in which the illustration of the detailed configuration of the active matrix substrate 1 is omitted.

As illustrated in FIG. 5, the counter substrate 2 includes a color filter layer (51) on one surface of a filter substrate 52 made of glass and the like. The color filter layer (51) has such a configuration that respective areas of the three principal colors of R, G, and B are formed periodically in the X direction. Hereinafter, the blue color (B) area of the color filter layer (51) is denoted by “51b”, the red color (R) area of the same is denoted by “51r”, and the green color (G) area of the same is denoted by “51g. The color areas of the color filter layer 51 overlap the corresponding pixel electrodes 31, respectively, when viewed in a plan view.

At the boundaries between the color areas of the color filter layer 51, a black matrix areas 51BM are provided along the Y direction. The black matrix area 51BM is formed at such a position that it covers the source line 33 and the touch sensor line 22 when viewed in a plan view.

As illustrated in FIG. 5, at a boundary between the blue color area 51b and the red color area 51r, the touch sensor line 22 is offset toward the blue color area 51b side, to such an extent that it does not protrude from the black matrix area 51BM when viewed in a plan view. In other words, the touch sensor line 22 is arranged so that the center line C1 in the width direction of the touch sensor line 22 is positioned on the blue color area 51b side with respect to the boundary line between the blue color area 51b and the red color area 51r.

Further, though the illustration is omitted, the touch sensor line 22 is also offset to the blue color area 51b side at the boundary between the blue color area 51b and the green color area 51g.

On the other hand, at the boundary between the red color area 51r and the green color area 51g, as illustrated in FIG. 6, the touch sensor line 22 is arranged so as to overlap substantially equally with the red color area 51r and the green color area 51g. In other words, the touch sensor line 22 is arranged in such a manner that the center line C1 in the width direction of the touch sensor line 22 substantially coincides with the boundary line between the red color area 51r and the green color area 51g.

By arranging the touch sensor line 22 in such a manner that it is offset to the blue color area 51b side in this way, the following problem is solved.

As illustrated in FIGS. 5 and 6, both end surfaces in the X direction of the touch sensor line are tapered generally. A part of light that is obliquely incident on this tapered end surface from an end of the black matrix area is reflected at the tapered end surface, thereby being returned to the viewer side. Since it is difficult to strictly control the line width of the touch sensor line and the tapering angle of the end face during etching so that they are accurately uniform, the intensity of the reflection light from the end face varies partially. Accordingly, there is a problem that display irregularities caused by reflection light from the end faces of the touch sensor lines are visible.

The visibility of such display irregularities to a viewer is color-dependent. More specifically, display irregularities based on reflection light in the red color area 51r and the green color area 51g tend to be more easily viewed. On the other hand, display irregularities based on reflection light in the blue color area 51b are not likely to be viewed. This attributes to visibility characteristics of human eyes.

In the present embodiment, by offsetting the touch sensor line 22 toward the blue color area 51b side, the ratio of reflection light returned from the touch sensor line 22 to the viewer side can be decreased in the red color area 51r and the green color area 51g. In the blue color area 51b, however, the ratio of reflection light returned from the touch sensor line 22 toward the viewer side increases, but since this reflection light is hardly visible as described above, no problem of display irregularities occurs.

As described above, with the configuration of the present embodiment, display irregularities caused by the touch sensor lines 22 can be suppressed, with the line width of the touch sensor lines 22 being maintained.

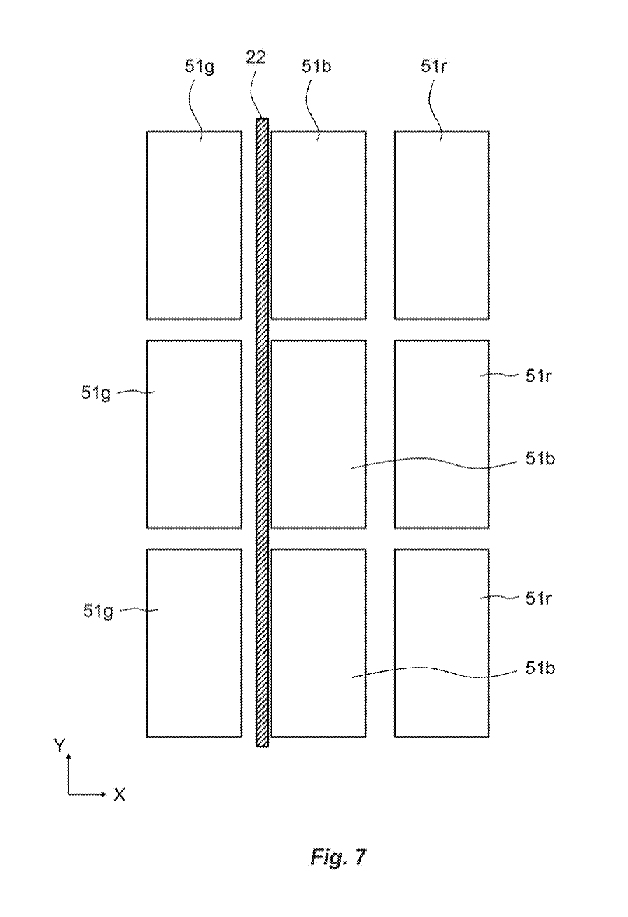

Incidentally, as illustrated in FIG. 7, the touch sensor lines 22 may be provided only on one side of the blue color area 51b. In the example illustrated in FIG. 7, the touch sensor line 22 is provided along the boundary between the blue color areas 51b and the green color areas 51g, but the touch sensor line 22 may be provided along the boundary between the red color areas 51r and the green color areas 51g. Further, within one touch panel, there may be a portion where the touch sensor line 22 is provided along the boundary between the blue color areas 51b and the green color areas 51g, and a portion where the touch sensor line 22 is provided along the boundary between the red color areas 51r and the green color areas 51g.

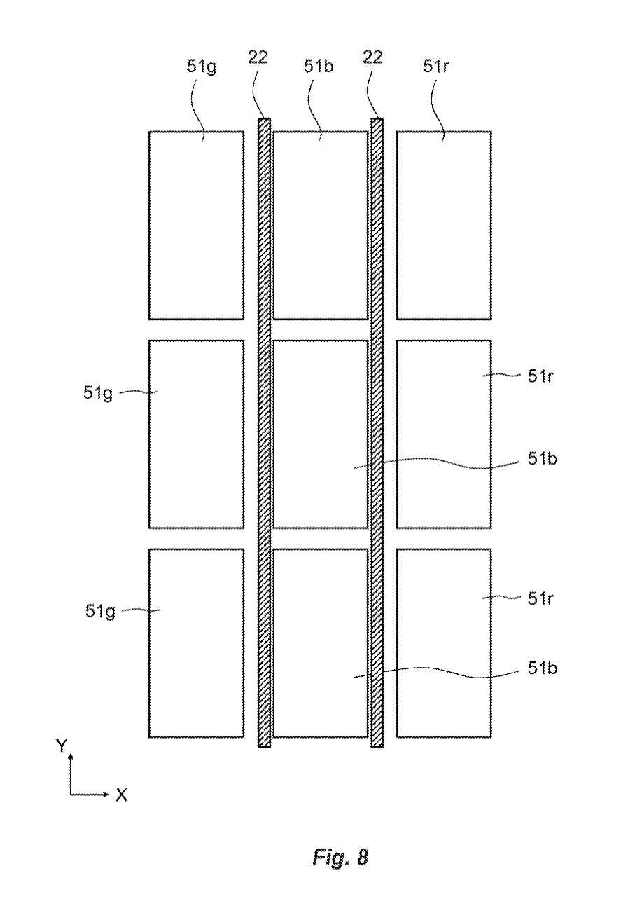

Alternatively, as illustrated in FIG. 8, the configuration may be such that two touch sensor lines 22 are formed on both opposite sides of the blue color area 51b. In this case, both of these two touch sensor lines 22 are preferably offset toward the sides of the blue color area 51b.

The present embodiment is described with reference to an example in which the color filter layer 51 includes areas of three principal colors, i.e., the blue color areas 51b, the red color areas 51r, and the green color areas 51g, but the color filter layer 51 may include, not only three principal colors, but also other colors.

### Embodiment 2

Other embodiments of the present invention are described below.

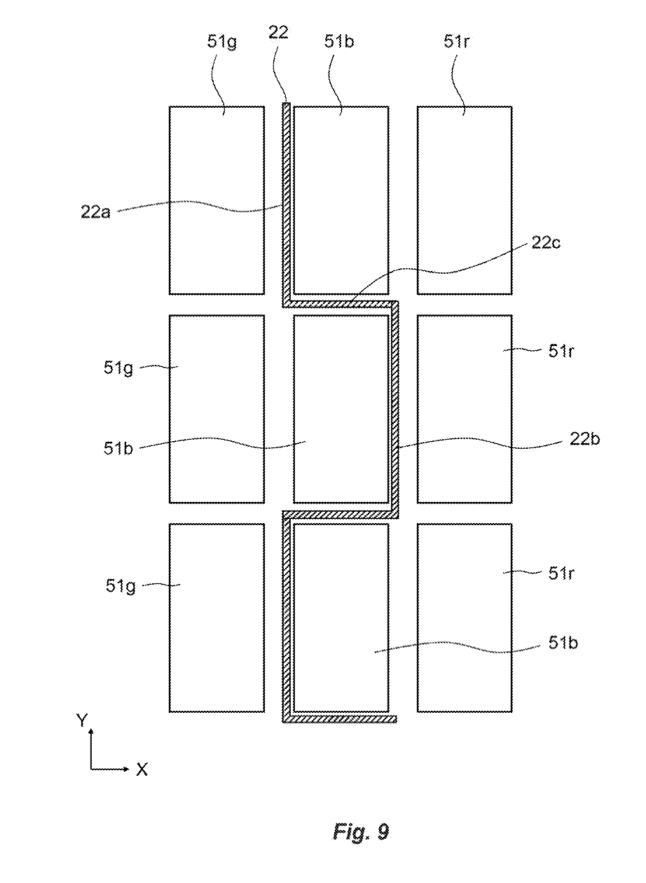

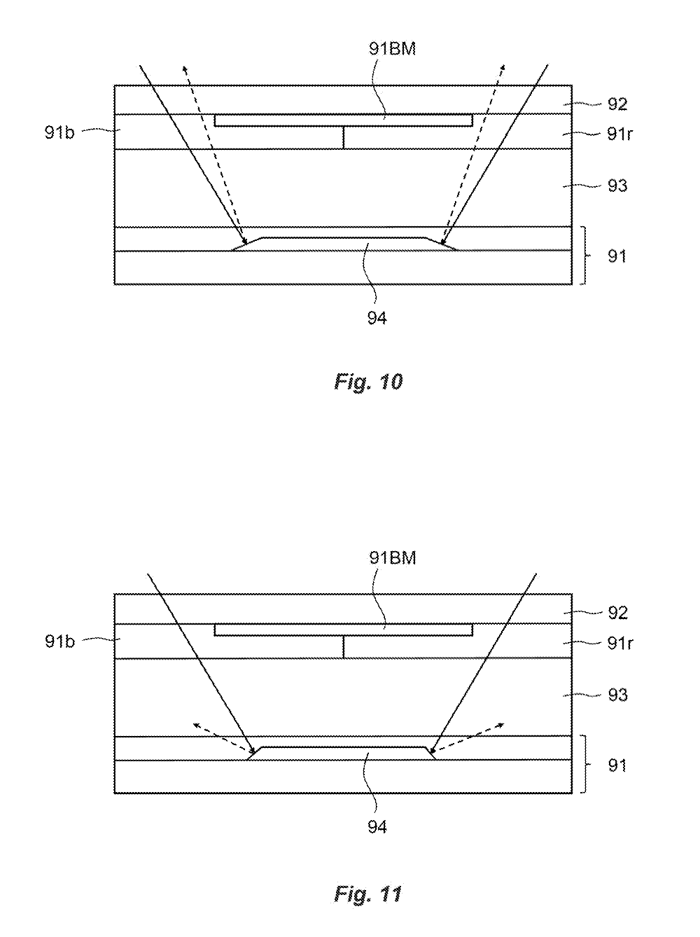

FIG. 9 is a schematic plan view illustrating a configuration of a touch sensor line 22 in a touch-panel-equipped display device according to Embodiment 2. As illustrated in FIG. 9, the touch-panel-equipped display device according to Embodiment 2 is different from that of Embodiment 1 in that the touch sensor line 22 is arranged on both opposite sides of the blue color area 51b, so as to be shaped in a zig-zag form.

More specifically, in the present embodiment, one touch sensor line 22 includes a portion that is arranged along the boundaries between the blue color area 51b and the green color area 51g (a first portion 22a in FIG. 9), and a portion that is arranged along the boundary between the blue color area 51b and the red color area 51r (a second portion 22b in FIG. 9). The first portion 22a and the second portion 22b are connected with each other by a line extending along the gate line 32 (a third portion 22c in FIG. 9).

Both of the first portion 22a and the second portion 22b are offset toward the blue color area 51b sides, respectively.

In this way, by arranging one touch sensor line 22 on both opposite sides of one row of blue color areas 51b in a zig-zag shape, the amounts of reflection light from the touch sensor line 22 on both opposite sides of the blue color areas 51b can be approximately equal to each other, which makes it possible to further reduce display irregularities.

Regarding the periodicity of the first portion 22a and the second portion 22b of the touch sensor line 22, in order to reduce display irregularities, it is most preferable that the first portion 22a and the second portion 22b are alternately provided every pixel region. In this case, however, there is disadvantage that the total length of the third portions 22c increases. The periodicity of the first portion 22a and the second portion 22b in the touch sensor line 22 may be decided appropriately, with the balance between display irregularities and the line resistance of the touch sensor line 22 being taken into consideration. Incidentally, the periodicity of the first portion 22a and the second portion 22b of the touch sensor line 22 is desirably uniform.

The above-described embodiment is merely an example for implementing the present invention. The present invention, therefore, is not limited to the above-described embodiment, and the above-described embodiment can be appropriately varied and implemented without departing from the spirit and scope of the invention.

The TFT 42, for example, is not limited to the bottom gate type TFT, but it may be the top gate type TFT. Besides, the semiconductor film 42b may be an oxide semiconductor film such as an indium tin zinc oxide (ITZO) film, amorphous silicon, or a film made of a semiconductor material such as low-temperature polysilicon (LTPS) or continuous grain silicon (CGS).

### DESCRIPTION OF REFERENCE NUMERALS

1: active matrix substrate
2: counter substrate
3: liquid crystal layer
10, 10A, 10B: touch-panel-equipped display device
21: counter electrode
22, 22A: touch sensor line
31: pixel electrode
42: TFT (display control element)
42a: gate electrode
42b: semiconductor film
42c: source electrode
42d: drain electrode
43: gate insulating film
44: first insulating film
45: flattening film
46: second insulating film
47: conductive film

1. A touch-panel-equipped display device comprising:
an active matrix substrate;
a counter substrate opposed to the active matrix substrate;
a liquid crystal layer interposed between the active matrix substrate and the counter substrate;
a display control element formed on the active matrix substrate;
a plurality of pixel electrodes formed on the active matrix substrate;
a plurality of counter electrodes that are formed on the active matrix substrate, electrostatic capacitors being formed between the counter electrodes and the pixel electrodes;
a control unit that supplies a touch driving signal to the counter electrodes so as to detect a touch position; and
a touch sensor line for connecting the control unit and the counter electrodes, and supplying the touch driving signal from the control unit to the counter electrodes,
wherein a color filter that includes at least a blue color area, a green color area, and a red color area is provided on the counter substrate, and
the touch sensor line is arranged so as to be offset toward a blue color area side at a boundary between the blue color area and another color area of the color filter.

2. The touch-panel-equipped display device according to claim 1,
wherein the touch sensor lines are arranged on both opposite sides of the blue color area of the color filter.

3. The touch-panel-equipped display device according to claim 1,
wherein the touch sensor line includes a first portion arranged on one of opposite sides of the blue color area of the color filter, a second portion arranged on the other one of the opposite sides of the blue color area of the color filter, and a third portion that connects the first portion and the second portion.

4. The touch-panel-equipped display device according to claim 3,
wherein the first portions and the second portions are arranged alternately every other pixel region.
